(19) United States
(12) Patent Application Publication
(10) Pub. No.: US 2025/0275227 A1
(43) Pub. Date: Aug. 28, 2025

(54) SEMICONDUCTOR DEVICE AND METHOD OF MANUFACTURING THE SAME

(71) Applicant: DENSO CORPORATION, Kariya-city (JP)

(72) Inventors: Masanori MIYATA, Kariya-city (JP); Hiroto SUGIURA, Kariya-city (JP); Atsushi SUGIMURA, Kariya-city (JP)

(21) Appl. No.: 19/206,638

(22) Filed: May 13, 2025

Related U.S. Application Data
(63) Continuation of application No. PCT/JP2023/032524, filed on Sep. 6, 2023.

(30) Foreign Application Priority Data
Dec. 2, 2022 (JP) 2022-193404

(51) Int. Cl. H10D 84/00; H10D 84/01

(52) U.S. Cl. CPC H10D 84/161; H10D 84/0109

(57) ABSTRACT

A semiconductor device has a transistor portion including a collector region and a diode portion including a cathode region. A semiconductor substrate has a buffer region in contact with the collector region and the cathode region. A p-type impurity concentration in the collector region and the cathode region ranges such that a first convex curve and a second convex curve located above the first convex curve are formed in the thickness direction. An n-type impurity concentration in the cathode region ranges in the thickness direction such that a third convex curve having a higher concentration than the first convex curve is formed within a thickness range of the first convex curve, and that a fourth convex curve having a higher concentration than the second convex curve is formed within a thickness range of the second convex curve.

### CROSS REFERENCE TO RELATED APPLICATIONS

The present application is a continuation application of International Patent Application No. PCT/JP2023/032524 filed on Sep. 6, 2023, which designated the U.S. and claims the benefit of priority from Japanese Patent Application No. 2022-193404 filed on Dec. 2, 2022. The entire disclosures of all of the above applications are incorporated herein by reference.

### TECHNICAL FIELD

The present disclosure relates to a semiconductor device and a method of manufacturing the semiconductor device.

### BACKGROUND

An IGBT (insulated gate bipolar transistor) has a p-type collector region and an n-type buffer region (field stop layer). The collector region is disposed within an area including a lower surface of a semiconductor substrate, and is in contact with a lower electrode. The buffer region is in contact with the collector region from the upper side.

### SUMMARY

According to an aspect of the present disclosure, a semiconductor device includes a semiconductor substrate, a lower electrode in contact with a lower surface of the semiconductor substrate, and a gate electrode. The semiconductor substrate has a p-type collector region in contact with the lower electrode, and an n-type cathode region in contact with the lower electrode. When the semiconductor substrate is viewed in the thickness direction, a transistor portion includes the collector region, and a diode portion includes the cathode region. The semiconductor substrate has a buffer region, a drift region, a body region, an emitter region, and an anode region. The buffer region is distributed across the transistor portion and the diode portion, and is in contact with the collector region and the cathode region from the upper side. The drift region is an n-type region distributed across the transistor portion and the diode portion, and has a lower n-type impurity concentration than the buffer region. The drift region is in contact with the buffer region from the upper side. The body region is disposed in the transistor portion and is a p-type region in contact with the drift region. The emitter region is disposed within the transistor portion and is an n-type region separated from the drift region by the body region. The anode region is disposed within the diode portion and is a p-type region in contact with the drift region. The gate electrode opposes the body region via a gate insulating film. The p-type impurity concentration in the collector region and the cathode region ranges to have a first convex curve and a second convex curve located above the first convex curve in a concentration distribution along the thickness direction. The first convex curve and the second convex curve are formed across the collector region and the cathode region. The n-type impurity concentration in the cathode region ranges in the concentration distribution along the thickness direction to have a third convex curve having a higher concentration than the first convex curve within a thickness range of the first convex curve, and a fourth convex curve having a higher concentration than the second convex curve within a thickness range of the second convex curve.

A method of manufacturing the semiconductor device includes a first implantation step, a second implantation step, a third implantation step, and a fourth implantation step. In the first implantation step, a p-type impurity is implanted into an implantation range corresponding to the cathode region and the collector region on the lower surface of the semiconductor substrate to form the first convex curve. In the second implantation step, a p-type impurity is implanted into an implantation range on the lower surface of the semiconductor substrate corresponding to the cathode region and the collector region to form the second convex curve. In the third implantation step, an n-type impurity is implanted into an implantation range on the lower surface of the semiconductor substrate corresponding to the cathode region to form the third convex curve. In the fourth implantation step, an n-type impurity is implanted into an implantation range on the lower surface of the semiconductor substrate corresponding to the cathode region to form the fourth convex curve. The first implantation step, the second implantation step, the third implantation step, and the fourth implantation step are performed such that the second convex curve is located above the first convex curve, that the third convex curve having a higher concentration than the first convex curve is formed within a thickness range of the first convex curve, and that the fourth convex curve having a higher concentration than the second convex curve is formed within a thickness range of the second convex curve.

### BRIEF DESCRIPTION OF DRAWINGS

FIG. 1 is a cross-sectional view of a semiconductor device according to a first embodiment.

FIG. 2 is a graph showing an impurity concentration distribution in a collector region.

FIG. 3 is a graph showing an impurity concentration distribution in a cathode region.

FIG. 4 is a graph showing an impurity concentration distribution in a cathode region of a semiconductor device of a comparative example.

FIG. 5 is an explanatory diagram of manufacturing the semiconductor device of the first embodiment.

FIG. 6 is an explanatory diagram of manufacturing the semiconductor device of the first embodiment.

FIG. 7 is a graph showing a relationship between a dose in a third implantation step and a forward voltage drop of a diode.

FIG. 8 is a cross-sectional view of a semiconductor device according to a second embodiment.

FIG. 9 is an explanatory diagram of manufacturing the semiconductor device of the second embodiment.

FIG. 10 is a cross-sectional view of a semiconductor device according to a third embodiment.

FIG. 11 is a cross-sectional view of a semiconductor device according to a fourth embodiment.

FIG. 12 is an explanatory diagram of manufacturing the semiconductor device of the fourth embodiment.

FIG. 13 is a graph showing an impurity concentration distribution in a cathode region of a semiconductor device according to a modification.

### DESCRIPTION OF EMBODIMENTS

An IGBT (insulated gate bipolar transistor) has a p-type collector region and an n-type buffer region (field stop layer). The collector region is disposed within an area including a lower surface of a semiconductor substrate, and is in contact with a lower electrode. The buffer region is in contact with the collector region from the upper side.

In the collector region, p-type impurity is ion-implanted multiple times to different depths. Therefore, in the collector region, plural convex curves are formed in the p-type impurity concentration along the thickness direction of the semiconductor substrate. By forming the collector region in this manner, the concentration of p-type impurity in the collector region can be increased in the vicinity of the buffer region. This improves the short circuit resistance of the IGBT.

A semiconductor element includes a diode provided adjacent to an IGBT. This type of semiconductor device is sometimes called an RC-IGBT (reverse conducting IGBT). In an RC-IGBT, a cathode region (an n-type region) of a diode is provided adjacent to the collector region of the IGBT. The buffer region is in contact with the collector region and the cathode region from the upper side. When forming the above-mentioned multiple convex curve distributions in the collector region of an RC-IGBT, the following steps are usually carried out. First, p-type impurity is implanted multiple times to different depths in the range corresponding to the collector region and the cathode region. Next, n-type impurity is implanted into a region corresponding to the cathode region at a concentration higher than that of the p-type impurity. Thus, an n-type cathode region is formed. However, with this method, a region in which the p-type impurity concentration is distributed in a convex curve shape may remain as a p-type region between the cathode region and the buffer region. If a p-type region remains between the cathode region and the buffer region in this manner, the diode cannot achieve the desired characteristics. This specification proposes a semiconductor device for obtaining good diode characteristics in an RC-IGBT in which plural convex curve distributions of p-type impurity concentration are formed in the collector region.

According to an aspect of the present disclosure, a semiconductor device includes a semiconductor substrate, a lower electrode in contact with a lower surface of the semiconductor substrate, and a gate electrode. The semiconductor substrate has a p-type collector region in contact with the lower electrode, and an n-type cathode region in contact with the lower electrode. When the semiconductor substrate is viewed in the thickness direction, a transistor portion includes the collector region. When the semiconductor substrate is viewed in the thickness direction, a diode portion includes the cathode region. The semiconductor substrate has a buffer region, a drift region, a body region, an emitter region, and an anode region. The buffer region is distributed across the transistor portion and the diode portion, and is in contact with the collector region and the cathode region from the upper side. The drift region is an n-type region distributed across the transistor portion and the diode portion, and has a lower n-type impurity concentration than the buffer region. The drift region is in contact with the buffer region from the upper side. The body region is disposed in the transistor portion and is a p-type region in contact with the drift region. The emitter region is disposed within the transistor portion and is an n-type region separated from the drift region by the body region. The anode region is disposed within the diode portion and is a p-type region in contact with the drift region. The gate electrode faces the body region via a gate insulating film. The p-type impurity concentration in the collector region and the cathode region is distributed such that a first convex curve and a second convex curve located above the first convex curve are formed in the concentration distribution along the thickness direction. The first convex curve and the second convex curve are formed across the collector region and the cathode region. The n-type impurity concentration in the cathode region is distributed in the concentration distribution along the thickness direction such that a third convex curve having a higher concentration than the first convex curve is formed within a thickness range of the first convex curve, and a fourth convex curve having a higher concentration than the second convex curve is formed within a thickness range of the second convex curve.

According to this configuration, within the thickness range of the first convex curve of the p-type impurity, the third convex curve of the n-type impurity having a higher concentration than the first convex curve is formed, so that this range can be made n-type. Furthermore, since the fourth convex curve having a higher concentration than the second convex curve is formed within the thickness range of the second convex curve of the p-type impurity, this range can be made n-type. Therefore, an n-type cathode region can be formed in the depth range from the lower electrode to the buffer region, and a p-type region can be restricted from remaining between the cathode region and the buffer region. Therefore, with this configuration, good diode characteristics can be obtained.

A method of manufacturing a semiconductor device includes a first implantation step, a second implantation step, a third implantation step, and a fourth implantation step. The semiconductor device includes a semiconductor substrate, a lower electrode in contact with a lower surface of the semiconductor substrate, and a gate electrode. The semiconductor substrate has: a p-type collector region in contact with the lower electrode; an n-type cathode region in contact with the lower electrode; a buffer region that is an n-type region having a lower n-type impurity concentration than the cathode region and in contact with the collector region and the cathode region from the upper side: a drift region that is an n-type region having a lower n-type impurity concentration than the buffer region and in contact with the buffer region from the upper side; a p-type body region in contact with the drift region and located above the collector region; an n-type emitter region separated from the drift region by the body region and located above the collector region; and a p-type anode region in contact with the drift region and located above the collector region. The gate electrode faces the body region via a gate insulating film.

In the first implantation step, a p-type impurity is implanted into an implantation range corresponding to the cathode region and the collector region on the lower surface of the semiconductor substrate to form the first convex curve in the thickness direction of the semiconductor substrate. In the second implantation step, a p-type impurity is implanted into an implantation range on the lower surface of the semiconductor substrate corresponding to the cathode region and the collector region to form the second convex curve in the thickness direction of the semiconductor substrate. In the third implantation step, an n-type impurity is implanted into an implantation range on the lower surface of the semiconductor substrate corresponding to the cathode region to form the third convex curve in the thickness direction of the semiconductor substrate. In the fourth implantation step, an n-type impurity is implanted into an implantation range on the lower surface of the semiconductor substrate corresponding to the cathode region to form the fourth convex curve in the thickness direction of the semiconductor substrate. The first implantation step, the second implantation step, the third implantation step, and the fourth implantation step are performed such that the second convex curve is located above the first convex curve, that the third convex curve having a higher concentration than the first convex curve is formed within a thickness range of the first convex curve, and that the fourth convex curve having a higher concentration than the second convex curve is formed within a thickness range of the second convex curve.

The first implantation step, the second implantation step, the third implantation step and the fourth implantation step may be performed in any order.

Accordingly, a semiconductor device having good diode characteristics can be manufactured.

In one example of the semiconductor device, a part of the cathode region having the third convex curve may be a first cathode region, and a part of the cathode region having the fourth convex curve may be a second cathode region. The semiconductor substrate may have a p-type boundary region disposed within the diode portion and adjacent to the transistor portion. The p-type boundary region is continuous with the collector region and in contact with the first cathode region from the upper side.

According to this configuration, the on-voltage of the IGBT can be reduced.

In the semiconductor device, trenches may be provided in the upper surface of the semiconductor substrate at interval in a lateral direction from the transistor portion toward the diode portion. The gate electrode may be disposed in each of the trenches in the transistor portion. A dummy electrode having a potential independent of the gate electrode may be disposed in the trench in the diode portion. A gap may be provided along the lateral direction between the trench in which the gate electrode is disposed that is located closest to the diode portion and an end of the cathode region adjacent to the transistor portion.

According to this configuration, the on-voltage of the IGBT can be reduced.

In the semiconductor device, plural cathode regions may be provided at interval within the diode portion.

This configuration makes it possible to reduce the recovery surge of the diode.

In the semiconductor device, the fourth convex curve may have plural maximum values in the concentration distribution along the thickness direction.

In the manufacturing method, an end of the implantation range of the third implantation step adjacent to the collector region may be positioned closer to the collector region than an end of the implantation range of the fourth implantation step adjacent to the collector region.

According to this configuration, the on-voltage of the IGBT can be reduced.

In the manufacturing method, in the third implantation step and the fourth implantation step, the n-type impurity may be implanted into plural implantation ranges spaced apart from each other on the lower surface of the semiconductor substrate.

This configuration makes it possible to reduce the recovery surge of the diode.

In the manufacturing method, in the fourth implantation step, the n-type impurity may be implanted multiple times at different implantation depths to form the fourth convex curve having multiple maximum values.

The manufacturing method may further include a step of activating the n-type impurity in the cathode region by laser annealing. In the first implantation step, the n-type impurity may be implanted at a dose of 2×10¹⁵ cm⁻² or more.

This configuration makes it possible to reduce the forward voltage drop of the diode.

### First Embodiment

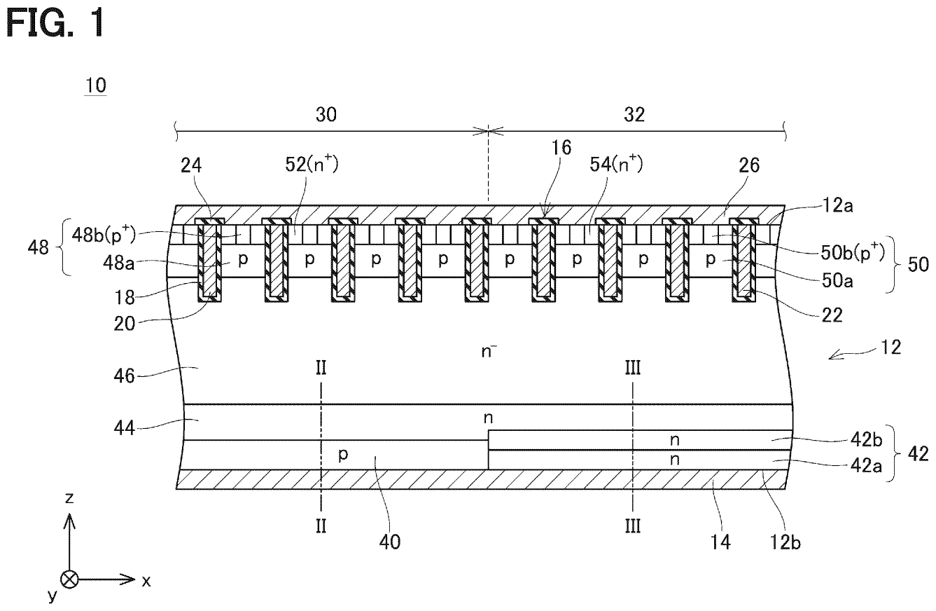

As illustrated in FIG. 1, a semiconductor device 10 according to a first embodiment includes a semiconductor substrate 12. The semiconductor substrate 12 is made of silicon. A lower electrode 14 is provided on the lower surface 12b of the semiconductor substrate 12. The lower electrode 14 covers almost the entire area of the lower surface 12b. A p-type collector region 40 and an n-type cathode region 42 are provided inside the semiconductor substrate 12, within a range facing the lower surface 12b of the semiconductor substrate 12. The collector region 40 and the cathode region 42 are in ohmic contact with the lower electrode 14. In the following, the semiconductor region including the collector region 40 when the semiconductor substrate 12 is viewed in the thickness direction is referred to as a transistor portion 30, and the semiconductor region including the cathode region 42 when the semiconductor substrate 12 is viewed in the thickness direction is referred to as a diode portion 32. A direction along the upper surface 12a of the semiconductor substrate 12 is referred to as x direction, and a direction along the upper surface 12a and perpendicular to the x direction is referred to as y direction. A thickness direction of the semiconductor substrate 12 is referred to as z direction. The x direction is defined as direction from the transistor portion 30 toward the diode portion 32. The y direction is along the boundary between the transistor portion 30 and the diode portion 32.

Multiple trenches 16 are provided in the upper surface 12a of the semiconductor substrate 12. Each of the trenches 16 extends linearly in the y direction on the upper surface 12a. The trenches 16 are arranged at interval in the x direction. The trenches 16 are provided in each of the transistor portion 30 and the diode portion 32. An inner surface of each of the trenches 16 is covered with a gate insulating film 18. A gate electrode 20 is disposed in each of the trenches 16 in the transistor portion 30. The gate electrode 20 is insulated from the semiconductor substrate 12 by the gate insulating film 18. A dummy electrode 22 is disposed in each of the trenches 16 in the diode portion 32. Each dummy electrode 22 is insulated from the semiconductor substrate 12 by the gate insulating film 18. The upper surfaces of the gate electrode 20 and the dummy electrode 22 are covered with an interlayer insulating film 24. An upper electrode 26 is provided on the upper part of the semiconductor substrate 12. The upper electrode 26 covers the upper surface of the interlayer insulating film 24 and the upper surface 12a of the semiconductor substrate 12. The dummy electrode 22 is connected to the upper electrode 26 at a position not shown. Therefore, the potential of the dummy electrode 22 is equal to the potential of the upper electrode 26. The gate electrode 20 is insulated from the upper electrode 26 and the dummy electrode 22. Therefore, the potential of the dummy electrode 22 is independent of the potential of the gate electrode 20. The gate electrode 20 is connected to a gate pad (not shown). The potential of the gate electrode 20 is controlled by an external drive circuit via a gate pad.

The semiconductor substrate 12 has a buffer region 44, a drift region 46, a body region 48, an anode region 50, an emitter region 52, and a dummy emitter region 54.

The buffer region 44 is an n-type region having a lower n-type impurity concentration than the cathode region 42. The buffer region 44 is distributed across the transistor portion 30 and the diode portion 32. The buffer region 44 is in contact with the collector region 40 and the cathode region 42 from the upper side.

The drift region 46 is an n-type region having a lower n-type impurity concentration than the buffer region 44. The drift region 46 is distributed across the transistor portion 30 and the diode portion 32. The buffer region 44 is in contact with the buffer region 44 from the upper side in the transistor portion 30 and the diode portion 32. The upper end of the drift region 46 is located above the lower end of the trench 16. The drift region 46 is in contact with the gate insulating film 18 on the side surface of each trench 16.

The body region 48 and the anode region 50 are p-type regions in contact with the drift region 46 from the upper side. The body region 48 is provided in the transistor portion 30, and the anode region 50 is provided in the diode portion 32. In other words, the p-type region arranged above the drift region 46 has the body region 48 within the transistor portion 30, and the anode region 50 within the diode portion 32.

The body region 48 includes a low concentration region 48a and a contact region 48b. The p-type impurity concentration of the low concentration region 48a is lower than the p-type impurity concentration of the contact region 48b. The low concentration region 48a is in contact with the drift region 46 from the upper side. The low concentration region 48a is in contact with the gate insulating film 18 above the drift region 46. The contact region 48b is in contact with the low concentration region 48a from the upper side. The contact region 48b is in ohmic contact with the upper electrode 26.

The anode region 50 includes a low concentration region 50a and a contact region 50b. The p-type impurity concentration of the low concentration region 50a is lower than the p-type impurity concentration of the contact region 50b. The low concentration region 50a is in contact with the drift region 46 from the upper side. The low concentration region 50a is in contact with the gate insulating film 18 above the drift region 46. The contact region 50b is in contact with the low concentration region 50a from the upper side. The contact region 50b is in ohmic contact with the upper electrode 26.

The emitter regions 52 are n-type regions disposed within the transistor portion 30. Each emitter region 52 is in contact with the low concentration region 48a from the upper side. Each emitter region 52 is in ohmic contact with the upper electrode 26. Each emitter region 52 is in contact with the gate insulating film 18 above the low concentration region 48a. Each emitter region 52 is separated from the drift region 46 by the low concentration region 48a. Each gate electrode 20 faces the low concentration region 48a located between the emitter region 52 and the drift region 46 via the gate insulating film 18.

The dummy emitter regions 54 are n-type regions arranged within the diode portion 32. Each dummy emitter region 54 is in contact with the low concentration region 50a from the upper side. Each dummy emitter region 54 is in contact with the gate insulating film 18 above the low concentration region 50a. Each dummy emitter region 54 is separated from the drift region 46 by the low concentration region 50a. Each dummy emitter region 54 is in ohmic contact with the upper electrode 26. The dummy emitter region 54 may not be provided in the diode portion 32.

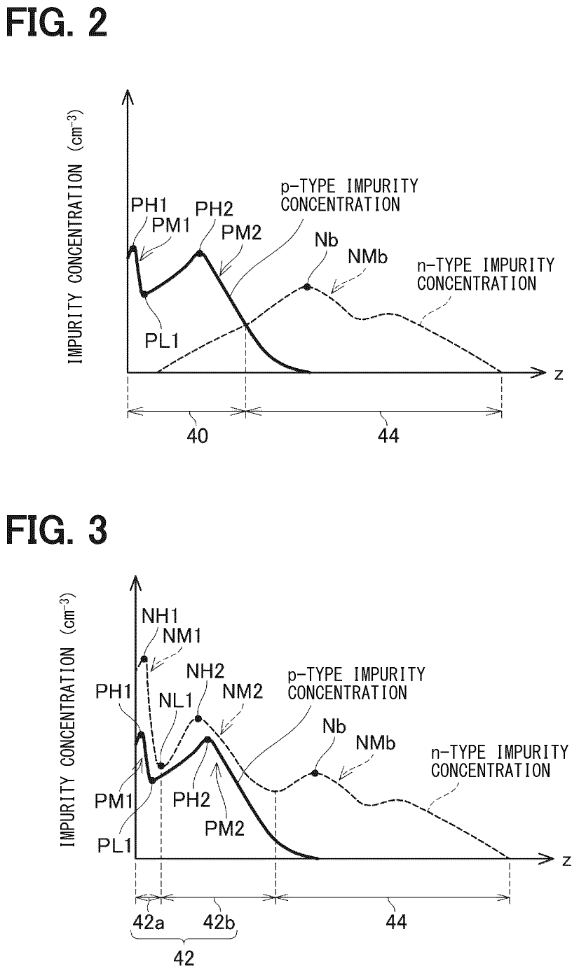

FIG. 2 shows the impurity concentration distribution at positions along line II-II in FIG. 1. That is, FIG. 2 shows the impurity concentration distribution in the collector region 40 and the buffer region 44 along the z direction. As shown in FIG. 2, the p-type impurity concentration is higher than the n-type impurity concentration in the collector region 40, and the n-type impurity concentration is higher than the p-type impurity concentration in the buffer region 44.

In the buffer region 44, the n-type impurity concentration is distributed to form a convex curve NMb having a maximum value Nb.

In the collector region 40, the p-type impurity concentration is distributed to form two convex curves PM1 and PM2. The convex curve PM1 has an upward protrusion shape having a maximum value PH1, and the convex curve PM2 has an upward protrusion shape having a maximum value PH2. The convex curve PM2 is located higher than the convex curve PM1. In other words, the convex curve PM2 is located at a position closer to the buffer region 44 than the convex curve PM1. In FIG. 2, the maximum value PH1 is higher than the maximum value PH2, but the maximum value PH1 may be lower than the maximum value PH2. A minimum value PL1 is formed at the boundary between the convex curve PM1 and the convex curve PM2.

FIG. 3 shows the impurity concentration distribution at positions along line III-III in FIG. 1. That is, FIG. 3 shows the impurity concentration distribution along the z direction in the cathode region 42 and the buffer region 44.

The convex curve NMb of the n-type impurity concentration in the buffer region 44 is formed across the transistor portion 30 and the diode portion 32. That is, the convex curve NMb is formed continuously in the x direction and the y direction. Therefore, as shown in FIG. 3, the convex curve NMb is formed in the buffer region 44 of the diode portion 32.

The convex curve PM1, PM2 of the p-type impurity concentration is formed across the transistor portion 30 and the diode portion 32 within the depth range of the collector region 40 (i.e., the range in the z direction). That is, the convex curve PM1, PM2 of the p-type impurity concentration is formed across the collector region 40 and the cathode region 42. In other words, the convex curve PM1, PM2 is formed continuously in the x direction and the y direction. Therefore, as shown in FIG. 3, the convex curve PM1, PM2 is formed in the cathode region 42.

In the cathode region 42, the n-type impurity concentration is higher than the p-type impurity concentration. In the cathode region 42, the n-type impurity concentration is distributed to form two convex curves NM1 and NM2. The convex curve NM1 has an upward protrusion shape having a maximum value NH1, and the convex curve NM2 has an upward protrusion shape having a maximum value NH2. The convex curve NM2 is located above the convex curve NM1 (i.e., at a position closer to the buffer region 44). In FIG. 3, the maximum value NH1 is higher than the maximum value NH2, but the maximum value NH1 may be lower than the maximum value NH2. A minimum value NL1 is formed at the boundary between the convex curve NM1 and the convex curve NM2. The minimum value NL1 is smaller than the maximum value PH1, PH2. The convex curve NM1 is formed at a position overlapping with the convex curve PM1. Either the maximum value NH1 of the convex curve NM1 or the maximum value PH1 of the convex curve PM1 may be located on the upper side (i.e., adjacent to the buffer region 44). The convex curve NM2 is formed to overlap with the convex curve PM2. Either the maximum value NH2 of the convex curve NM2 or the maximum value PH2 of the convex curve PM2 may be located on the upper side (i.e., adjacent to the buffer region 44). The convex curve NM1, NM2 is formed to overlap with the convex curve PM1, PM2, so that the n-type impurity concentration is higher than the p-type impurity concentration in the entire cathode region 42. In the following, a part of the cathode region 42 in which the convex curve NM1 is formed is referred to as a first cathode region 42a, and a part of the cathode region 42 in which the convex curve NM2 is formed is referred to as a second cathode region 42b.

In the transistor portion 30, an IGBT is formed by the emitter region 52, the body region 48, the drift region 46, the buffer region 44, the collector region 40, the gate electrode 20, and the gate insulating film 18. When the potential of the lower electrode 14 is higher than the potential of the upper electrode 26 and the potential of the gate electrode 20 is higher than the gate threshold, the IGBT turns on and current flows in the transistor portion 30 from the lower electrode 14 to the upper electrode 26. In the collector region 40, the two convex curves PM1 and PM2 are formed in the z direction. Since the convex curve PM2 is formed in the vicinity of the buffer region 44, the collector region 40 has a high p-type impurity concentration in the vicinity of the buffer region 44. For this reason, the IGBT has a high short-circuit resistance.

In the diode portion 32, a diode is formed by the anode region 50, the drift region 46, the buffer region 44, and the cathode region 42. When the potential of the upper electrode 26 is higher than the potential of the lower electrode 14, the diode turns on and current flows in the diode portion 32 from the upper electrode 26 to the lower electrode 14.

FIG. 4 shows a comparative example with an impurity concentration distribution in a buffer region 44 and a cathode region 42 of a semiconductor device. FIG. 4 differs from FIG. 3 in that the convex curve NM2 is not formed. If the convex curve NM2 is not formed as in FIG. 4, the p-type impurity concentration will be higher than the n-type impurity concentration in the range of the convex curve PM2. Therefore, a p-type region is formed between the first cathode region 42a and the buffer region 44. When the p-type region is formed between the first cathode region 42a and the buffer region 44 in this manner, it becomes difficult for a current to flow through the diode, and the forward voltage drop of the diode becomes extremely high. Thus, high losses occur in the diode. In contrast to this, in the semiconductor device of the first embodiment, the convex curve NM2 is formed, so that the first cathode region 42a and the buffer region 44 are connected by the n-type second cathode region 42b. Therefore, the loss occurring in the diode can be suppressed.

Next, a manufacturing method of the semiconductor device 10 will be described. This manufacturing method has a collector region forming step in which the collector region is formed and a cathode region forming step in which the cathode region is formed, which will be described below.

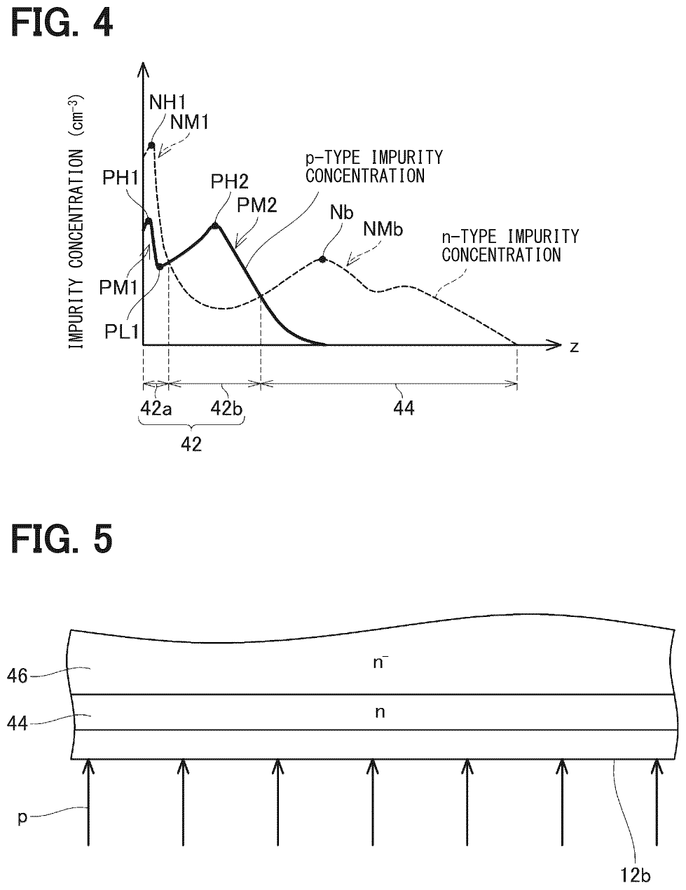

In the collector region forming step, as shown in FIG. 5, p-type impurity is implanted into the lower surface 12b of the semiconductor substrate 12 in which the buffer region 44 is formed. The p-type impurity is implanted into the entire lower surface 12b of the semiconductor substrate 12. That is, the p-type impurity is implanted into a region of the lower surface 12b that corresponds to the cathode region 42 and a region of the lower surface 12b that corresponds to the collector region 40. The collector region forming step includes a first implantation step and a second implantation step having different implantation depths. In the first implantation step, the p-type impurity is implanted so that the average stopping position of the p-type impurity is at the depth of the maximum value PH1. In the second implantation step, the p-type impurity is implanted so that the average stopping position of the p-type impurity is at the depth of the maximum value PH2. That is, in the second implantation step, the implantation energy of the p-type impurity is set higher than that in the first implantation step, and the p-type impurity is implanted deeper than that in the first implantation step. By carrying out the first implantation step and the second implantation step in this manner, when the p-type impurity is subsequently diffused and activated, the convex curves PM1 and PM2 are formed.

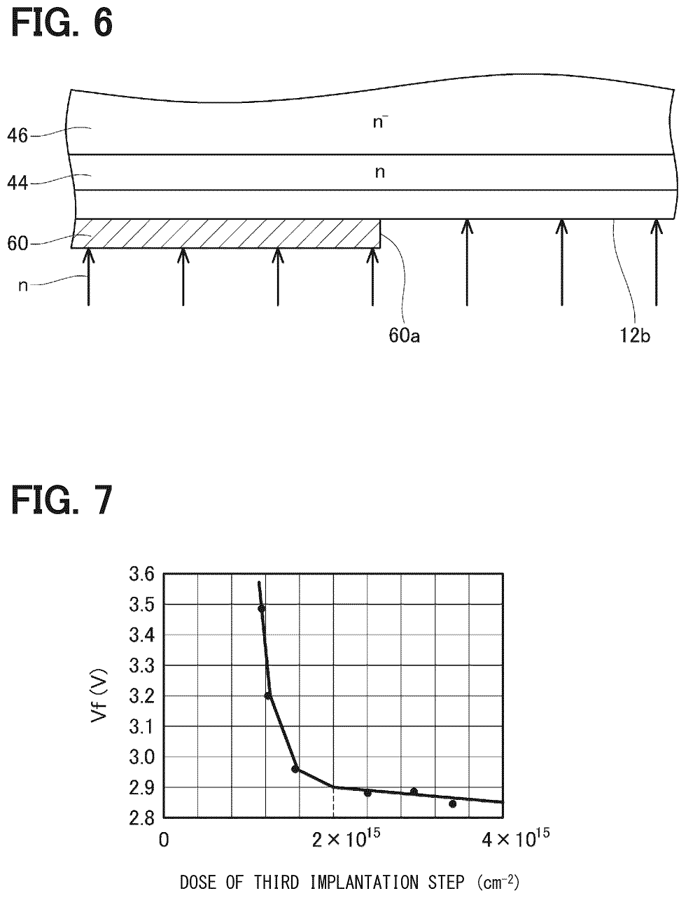

Next, the cathode region forming step is carried out. In the cathode region forming step, a mask 60 is formed on the lower surface 12b of the semiconductor substrate 12, as shown in FIG. 6. The mask 60 has an opening 60a. An area of the lower surface 12b corresponding to the cathode region 42 is exposed due to the opening 60a. An area of the lower surface 12b corresponding to the collector region 40 is covered with the mask 60. Next, n-type impurity is implanted into the lower surface 12b of the semiconductor substrate 12 through the mask 60. The n-type impurity is not implanted into the area corresponding to the collector region 40, but is implanted into the area corresponding to the cathode region 42. The cathode region forming step includes a third implantation step and a fourth implantation step having different implantation depths. In the third implantation step, the n-type impurity is implanted so that the average stopping position of the n-type impurity is at the depth of the maximum value NH1. In the fourth implantation step, the n-type impurity is implanted so that the average stopping position of the n-type impurity is at the depth of the maximum value NH2. That is, in the fourth implantation step, the implantation energy of the n-type impurity is set higher than that in the third implantation step, and the n-type impurity is implanted deeper than that in the third implantation step. By carrying out the third and fourth implantation steps in this manner, when the n-type impurity is subsequently diffused and activated, the convex curves NM1 and NM2 are formed. The dose of the third implantation step (i.e., the dose for the convex curve NM1) is higher than the dose of the first implantation step (i.e., the dose for the convex curve PM1). Moreover, the dose of the fourth implantation step (i.e., the dose for the convex curve NM2) is higher than the dose of the second implantation step (i.e., the dose for the convex curve PM2). After the n-type impurity is implanted, the mask 60 is removed.

Next, the lower surface 12b of the semiconductor substrate 12 is irradiated with a laser, thereby annealing the semiconductor substrate 12. This heats the areas into which the n-type and p-type impurities are implanted, to diffuse and activate the implanted n-type and p-type impurities. When the n-type and p-type impurities diffuse, the impurity concentration distributions shown in FIGS. 2 and 3 are obtained. In order to recover the crystal defects to the depth of the convex curve NM2, PM2, the lower surface 12b is irradiated with a high-energy laser. When a laser is irradiated with high energy, the diffusion distance of the n-type impurity may become long in the range of the convex curve NM1, and the n-type impurity concentration may become low in the range of the convex curve NM1. When the n-type impurity concentration becomes low within the range of the convex curve NM1, the contact resistance of the first cathode region 42a with the lower electrode 14 becomes high, and the forward voltage drop of the diode becomes high. FIG. 7 shows a relationship between the dose of the third implantation step and the forward voltage drop Vf of the diode, relative to the convex curve NM1, when a high-energy laser is irradiated to repair crystal defects to the depth of the convex curve NM2, PM2. The forward voltage drop Vf shown in FIG. 7 is defined when 400 A flows through the diode. Even in the case of irradiating a laser with high energy, by setting the dose amount in the third implantation step to 2×10¹⁵ cm⁻² or more, as shown in FIG. 7, a sufficiently high n-type impurity concentration can be obtained in the first cathode region 42a, and the forward voltage drop Vf can be stabilized at a low value.

As described above, in this manufacturing method, in the collector region forming step, the p-type impurity is implanted not only into the area corresponding to collector region 40 but also into the area corresponding to cathode region 42. Therefore, no mask is required, and the p-type impurity can be easily implanted. Furthermore, in this manufacturing method, since the convex curve PM1, PM2 can be formed in the collector region 40, an IGBT having high short-circuit resistance can be formed. Furthermore, in this manufacturing method, in the collector region forming step, the third implantation step and the fourth implantation step are performed with different implantation depths, thereby forming the convex curves NM1, NM2. Therefore, the formation of a p-type region between the first cathode region 42a and the buffer region 44 can be restricted.

### Second Embodiment

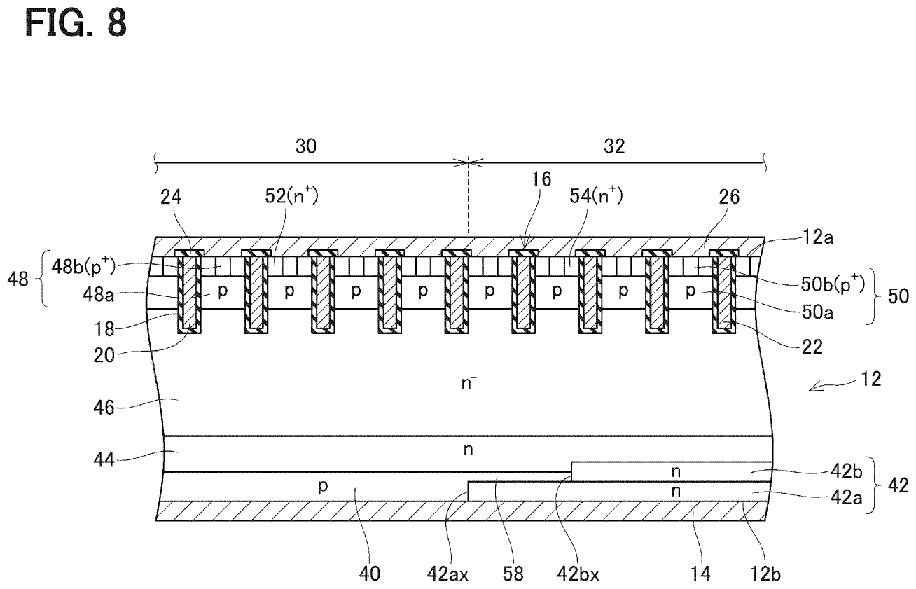

In a semiconductor device according to a second embodiment, as shown in FIG. 8, an end 42ax of the first cathode region 42a adjacent to the collector region 40 is located closer to the collector region 40 than an end 42bx of the second cathode region 42b adjacent to the collector region 40 is. Near the collector region 40, a p-type boundary region 58 is disposed above the first cathode region 42a. The boundary region 58 is disposed within the diode portion 32 adjacent to the transistor portion 30, and is continuous with the collector region 40. The boundary region 58 is in contact with the first cathode region 42a from the upper side.

In the semiconductor device of the second embodiment, when the IGBT is turned on, holes flow from the collector region 40 and the boundary region 58 into the drift region 46 in the transistor portion 30. For this reason, the density of holes in the drift region 46 in the transistor portion 30 tends to increase. Therefore, in the second embodiment, the on-resistance of the IGBT can be further reduced. Furthermore, in the semiconductor device of the second embodiment, when the diode is on, no current flows through the boundary region 58. Therefore, the current flowing through the diode is low. Thus, recovery surge is unlikely to occur in the diode.

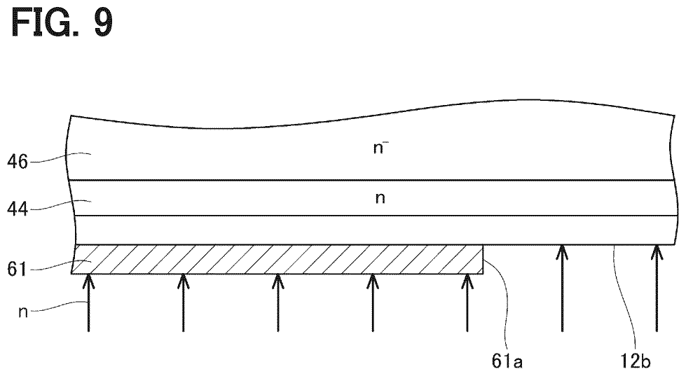

Next, a method of manufacturing the semiconductor device of the second embodiment will be described. In the second embodiment, the first implantation step, the second implantation step, and the third implantation step are performed in the same manner as in the first embodiment. In the fourth implantation step of the second embodiment (that is, the implantation step for the convex curve NM2), as shown in FIG. 9, n-type impurity is implanted into the lower surface 12b through a mask 61. The opening 61a of the mask 61 is smaller than the opening 60a of the mask 60. The mask 61 covers an area of the lower surface 12b that corresponds to the collector region 40 and the boundary region 58. Therefore, in the fourth implantation step, no n-type impurity is formed in the range corresponding to the boundary region 58, and the p-type boundary region 58 is formed.

### Third Embodiment

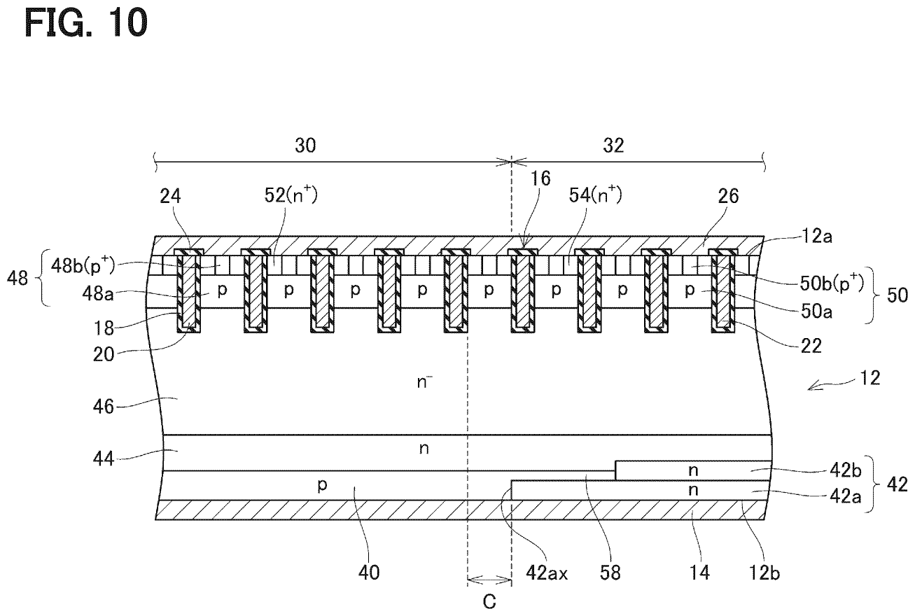

In a semiconductor device of a third embodiment, as shown in FIG. 10, a gap C is provided in the x direction between the trench 16 located closest to the cathode region 42, in which the gate electrode 20 is provided, (i.e., the trench 16 in the transistor portion 30) and an end of the cathode region 42. When the gap C is provided in this manner, the collector region 40 becomes wider, and the on-resistance of the IGBT can be reduced. Also, because the cathode region 42 is narrower, when the diode is on, the current that flows is lower. Therefore, recovery surge is unlikely to occur in the diode.

### Fourth Embodiment

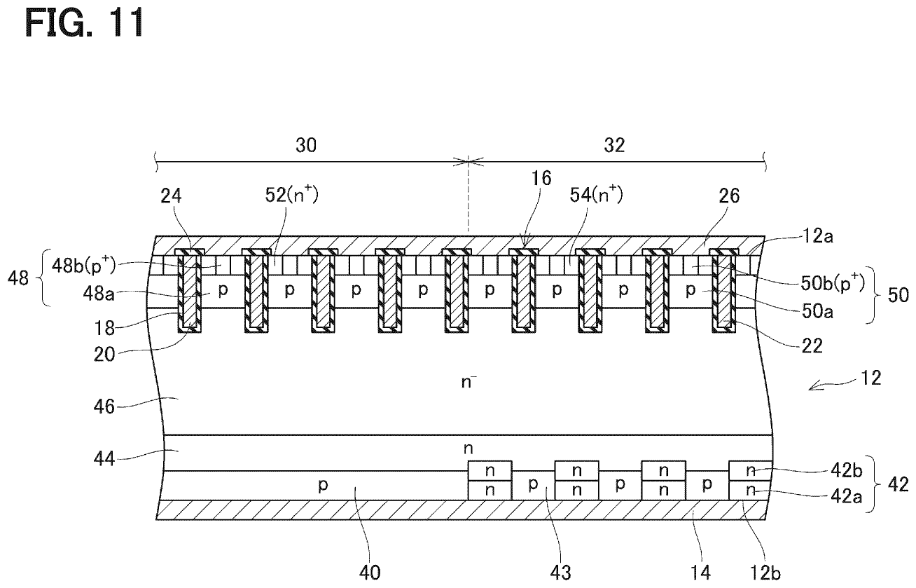

In a semiconductor device of a fourth embodiment, as shown in FIG. 11, plural cathode regions 42 are provided at interval in the diode portion 32. A p-type ineffective region 43 is disposed in the gap between the cathode regions 42. In this configuration, when the diode is on, no current flows through the ineffective region 43, so the current flowing through the diode is low. Therefore, recovery surge is unlikely to occur in the diode.

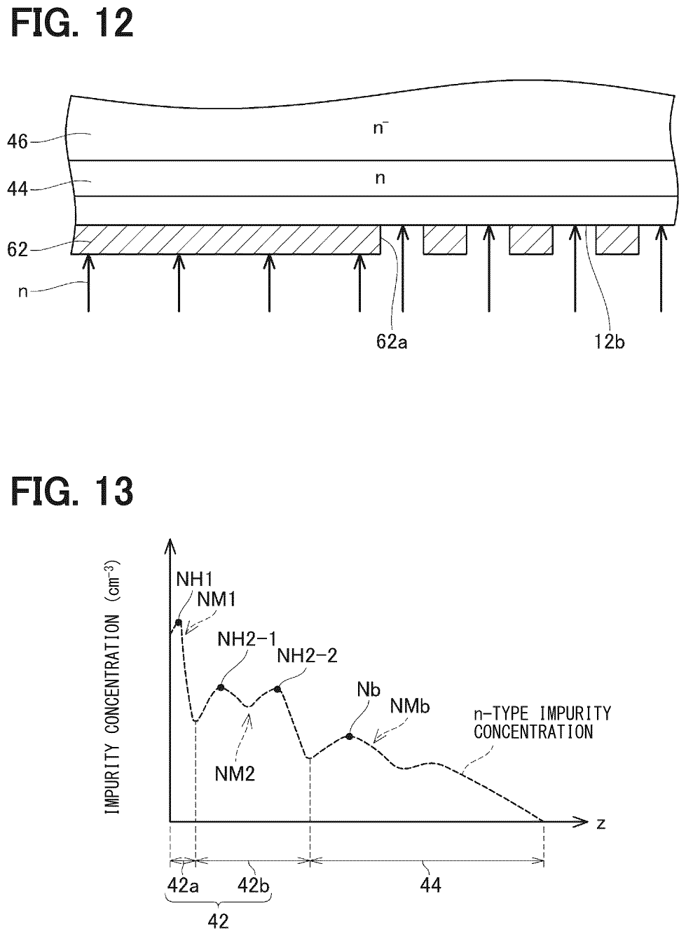

In the method of manufacturing the semiconductor device of the fourth embodiment, in the third and fourth implantation steps, as shown in FIG. 12, n-type impurity is implanted into the lower surface 12b through a mask 62. The mask 62 has plural openings 62a formed therein at interval. Therefore, as shown in FIG. 11, the plural cathode regions 42 can be formed.

In the embodiment, the convex curve NM2 has one maximum value NH2. However, as shown in FIG. 13, the convex curve NM2 in the second cathode region 42b may have plural maximum values NH2-1 and NH2-2. Such a distribution can be obtained by implanting the n-type impurity multiple times at different implantation depths in the fourth implantation step. Even with this configuration, the formation of a p-type region between the first cathode region 42a and the buffer region 44 can be restricted.

In the embodiment, the first implantation step, the second implantation step, the third implantation step, and the fourth implantation step are carried out in this order. However, these steps may be performed in any order. In the embodiment, the collector region and the cathode region are formed after the buffer region 44, but impurities may be implanted into the buffer region 44 after the collector region and the cathode region.

In the embodiment, the dummy electrode 22 is disposed in the trench 16 to have a potential independent of the gate electrode 20, in the diode portion 32. However, an electrode that is electrically connected to the gate electrode 20 may be disposed in the trench 16 in the diode portion 32. Furthermore, a trench may not be provided in the diode portion 32.

In the embodiment, the trench type IGBT is formed in the transistor portion. However, a planar type IGBT may be formed in the transistor portion.

The convex curve PM1 is an example of a first convex curve. The convex curve PM2 is an example of a second convex curve. The convex curve NM1 is an example of a third convex curve. The convex curve NM2 is an example of a fourth convex curve.

Although the embodiments have been described in detail above, these are merely examples and do not limit the scope of claims. The techniques described in claims include various modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve a plurality of objectives at the same time, and achieving one of the objectives itself has technical usefulness.

What is claimed is:

1. A semiconductor device comprising:
a semiconductor substrate;
a lower electrode in contact with a lower surface of the semiconductor substrate; and
a gate electrode, wherein
the semiconductor substrate includes a p-type collector region in contact with the lower electrode and an n-type cathode region in contact with the lower electrode,
the collector region is included in a transistor portion of the semiconductor substrate when viewed in a thickness direction,
the cathode region is included in a diode portion of the semiconductor substrate when viewed in the thickness direction,
the semiconductor substrate has:
a buffer region distributed across the transistor portion and the diode portion and in contact with the collector region and the cathode region from an upper side;
a drift region distributed across the transistor portion and the diode portion and in contact with the buffer region from an upper side, the drift region being an n-type region having a lower n-type impurity concentration than the buffer region;
a p-type body region disposed within the transistor portion and in contact with the drift region;
an n-type emitter region disposed within the transistor portion and separated from the drift region by the body region; and
a p-type anode region disposed within the diode portion and in contact with the drift region,
the gate electrode opposes the body region via a gate insulating film,
a p-type impurity concentration in the collector region and the cathode region ranges in a thickness direction to have a first convex curve and a second convex curve located above the first convex curve, and the first convex curve and the second convex curve are distributed across the collector region and the cathode region, and
an n-type impurity concentration in the cathode region ranges in a thickness direction to have a third convex curve having a higher concentration than the first convex curve within a thickness range of the first convex curve, and a fourth convex curve having a higher concentration than the second convex curve within a thickness range of the second convex curve.

2. The semiconductor device according to claim 1, wherein
the cathode region has a first cathode region including the third convex curve, and a second cathode region including the fourth convex curve,
the semiconductor substrate has a p-type boundary region located adjacent to the transistor portion within the diode portion, and
the p-type boundary region is continuous with the collector region and in contact with the first cathode region from an upper side.

3. The semiconductor device according to claim 1, wherein
a plurality of trenches is provided in an upper surface of the semiconductor substrate at interval in a lateral direction defined from the transistor portion toward the diode portion,
the gate electrode is disposed in each of the trenches within the transistor portion,
a dummy electrode having a potential independent of the gate electrode is disposed in each of the trenches within the diode portion, and
a gap is provided along the lateral direction between the trench closest to the diode portion and having the gate electrode and an end of the cathode region adjacent to the transistor portion.

4. The semiconductor device according to claim 1, wherein the cathode region is one of a plurality of cathode regions provided at interval within the diode portion.

5. The semiconductor device according to claim 1, wherein the fourth convex curve has a plurality of maximum values in a concentration distribution along the thickness direction.

6. The semiconductor device according to claim 1, wherein
a minimum value is formed at a boundary between the third convex curve and the fourth convex curve, and the minimum value is smaller than a maximum value of the first convex curve and a maximum value of the second convex curve.

7. The semiconductor device according to claim 1, wherein
a maximum value of the first convex curve is larger than a maximum value of the second convex curve in the collector region and the cathode region.

8. A method of manufacturing a semiconductor device comprising:
implanting a p-type impurity into an implantation range on a lower surface of a semiconductor substrate corresponding to a cathode region and a collector region to form a first convex curve in a thickness direction of the semiconductor substrate in a first implantation step;
implanting a p-type impurity into an implantation range on the lower surface of the semiconductor substrate corresponding to the cathode region and the collector region to form a second convex curve in the thickness direction of the semiconductor substrate in a second implantation step;
implanting an n-type impurity into an implantation range on the lower surface of the semiconductor substrate corresponding to the cathode region to form a third convex curve in the thickness direction of the semiconductor substrate in a third implantation step; and
implanting an n-type impurity into an implantation range on the lower surface of the semiconductor substrate corresponding to the cathode region to form a fourth convex curve in the thickness direction of the semiconductor substrate in a fourth implantation step, wherein
the first implantation step, the second implantation step, the third implantation step, and the fourth implantation step are performed such that the second convex curve is located above the first convex curve, that the third convex curve having a higher concentration than the first convex curve is formed within a thickness range of the first convex curve, and that the fourth convex curve having a higher concentration than the second convex curve is formed within a thickness range of the second convex curve.

9. The method according to claim 8, wherein an end of the implantation range of the third implantation step adjacent to the collector region is located closer to the collector region than an end of the implantation range of the fourth implantation step adjacent to the collector region.

10. The method according to claim 8, wherein in the third implantation step and the fourth implantation step, an n-type impurity is implanted into a plurality of implantation ranges spaced from each other on the lower surface of the semiconductor substrate.

11. The method according to claim 8, wherein in the fourth implantation step, an n-type impurity is implanted a plurality of times at different implantation depths to form the fourth convex curve having a plurality of maximum values.

12. The method according to claim 8, further comprising: activating an n-type impurity in the cathode region by laser annealing, wherein the n-type impurity is implanted at a dose of 2×10¹⁵ cm⁻² or more in the third implantation step.

13. The method according to claim 8, wherein in the third implantation step and the fourth implantation step, an n-type impurity is implanted to form a minimum value of n-type impurity concentration that is smaller than a maximum value of the first convex curve and a maximum value of the second convex curve, at a boundary between the third convex curve and the fourth convex curve.

14. The method according to claim 8, wherein in the first implantation step and the second implantation step, a p-type impurity is implanted such that a maximum value of the first convex curve is larger than a maximum value of the second convex curve.
